(19) United States
(12) Patent Application Publication
(10) Pub. No.: US 2026/0298995 A1
(43) Pub. Date: Oct. 1, 2026

(54) SYSTEM AND METHOD FOR INSPECTION OF CAR ELECTROMAGNETIC ACTUATORS USING A SCAN TOOL

(71) Applicant: Innova Electronics Corporation, Irvine, CA (US)

(72) Inventors: Keith ANDREASEN, Garden Grove, CA (US); Phuong PHAM, Fountain Valley, CA (US); Thuan Cong HUYNH, Ho Chi Minh City (VN); Ninh Tan DO, Ho Chi Minh City (VN); Tuan Quoc LE, Ho Chi Minh City (VN)

(21) Appl. No.: 19/089,835

(22) Filed: Mar. 25, 2025

(51) Int. Cl. G01R 31/00; G01R 31/327; G07C 5/08; G07C 5/10; G09B 5/02

(52) U.S. Cl. CPC G01R 31/007; G01R 31/3278; G07C 5/0825; G07C 5/10; G09B 5/02

(57) ABSTRACT

A system and method for diagnosing, locating, and testing vehicle electromechanical actuators, such as relays and solenoids, utilizes integrated on-board diagnostic (OBD) data, vehicle identification number (VIN) decoding, and cloud-based support systems. The system includes a diagnostic tool equipped with a test interface for bench-testing actuators and a user interface for displaying guided instructions. OBD and live data are retrieved and analyzed to identify faults in actuators, correlating diagnostic trouble codes (DTCs) and real-time data to specific components. VIN decoding enables precise identification of actuator specifications, locations, and associated wiring diagrams. The system further provides step-by-step in-vehicle testing or removal and testing instructions, simulates operating conditions for performance evaluation, and offers repair or replacement guidance. Cloud-based functionality integrates historical data, predictive analytics, and global updates for enhanced diagnostic accuracy and repair recommendations.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND

### 1. Technical Field

The present disclosure relates generally to testing and diagnosing relays. The disclosure is particularly related to isolating potentially faulty relays from a vehicle's diagnostic testing codes, assisting users to locate these relays and facilitating testing of these relays, while in the vehicle or removed and plugged into a tester unit.

### 2. Description of the Related Art

Relays play a key role in modern automobiles by controlling and managing various electrical systems. They function by enabling a low-current control circuit to operate a high-current load, preventing large currents from passing through control switches. This not only protects sensitive components but also improves overall reliability.

In automotive lighting, relays are used to switch between low-beam and high-beam headlights and to activate fog lights or auxiliary driving lights, allowing drivers to manage powerful lighting circuits with low-current switches. Cooling fans, which regulate engine temperature, are also controlled by relays. When the engine reaches a preset temperature, a relay powers the fans to maintain optimal engine performance.

Relays are important components for vehicle starting systems, engaging the starter motor with high current from a low-current ignition switch. They also control electric fuel pumps, ensuring they receive sufficient power when the engine is running or during startup. In the HVAC system, relays operate blower motors, allowing variable speeds and precise control over ventilation.

For convenience features, relays manage power windows and door locks, enabling small switches to control powerful motors. Windshield wipers also rely on relays to regulate different speeds and intermittent functions. Relays control the car horn, letting a low-current switch activate a relay to produce the horn sound with higher current flow.

In heated systems, relays manage current to heated seats and mirrors, preventing overloads on control switches. Rear window defoggers, which require substantial current, are similarly controlled by relays for reliable operation. Additionally, relays are used for battery isolation and load management, disconnecting specific systems when the vehicle is off or when the battery voltage drops too low.

Modern automobiles utilize both electromechanical (hereinafter “mechanical”) relays and electronic relays, also known as solid-state relays (SSRs), depending on the application and requirements. Each type has its own characteristics and ideal uses.

Mechanical relays operate using movable contacts controlled by an electromagnetic coil. When current flows through the coil, it creates a magnetic field that pulls the contacts together to complete a circuit. These relays are commonly used in applications requiring simple on/off control with relatively low switching speeds, such as in headlights, cooling fans, starter motors, horns, and power windows and locks. Mechanical relays are used for their affordability, reliability, and capacity to handle high current loads. However, they have moving parts that are prone to wear over time and produce an audible clicking sound when activated, which can be a drawback in certain situations.

Electronic Relays (Solid-State Relays or SSRs), in contrast, have no moving parts. They use semiconductor components like transistors, thyristors, or triacs to electronically switch circuits on and off. SSRs are known for their fast switching capabilities, higher reliability due to the absence of mechanical wear, and compact size. These features make them ideal for use in electronic control units (ECUs), advanced driver-assistance systems (ADAS), lighting systems with pulse-width modulation (PWM) control, engine management systems, and safety systems such as airbags. However, electronic relays can be more expensive, generate more heat, and are less suitable for handling very high current loads without additional cooling.

In modern vehicles, mechanical relays remain prevalent in simpler or higher-current applications, while electronic relays are increasingly adopted in areas that require greater precision, speed, and longer lifespans. The shift towards more electronic control modules, automated systems, driver assistance, and infotainment features is driving this trend.

Most car relays are replaceable, especially standard mechanical relays found in older and many modern vehicles. These relays are typically located in the fuse box or mounted separately and are often standardized in size, making them easy to find and install. These are commonly used for systems like headlights, fuel pumps, cooling fans, starter motors, power windows, and horns.

In contrast, solid-state relays, increasingly used in modern vehicles, are often part of electronic control units or printed circuit boards, and are not individually replaceable. In such cases, the entire control unit needs replacement if a relay within it fails. These are commonly found in advanced systems such as driver-assistance features, engine control modules, and safety systems.

Some modern vehicles have relays integrated into specific control modules like the Body Control Module (BCM) or Engine Control Module (ECM). In these cases, replacing a relay requires servicing or replacing the entire module. Additionally, certain manufacturers may design proprietary relays with unique specifications, which can still be replaced but may require obtaining a specific part from the manufacturer.

Relays include standardized contact pin numbers. These are standardized primarily by the DIN (Deutsches Institut für Normung) standards, specifically DIN 72552. This standard defines the numbering system for electrical terminals in vehicles, ensuring consistent relay and component connections across manufacturers.

| Relay | | |
|---|---|---|
| Pin | | |
| Number | Description | Function |
| 30 | Common | Connects to the power source, providing input |
| | (Power Input) | voltage to the relay. |
| 87 | Normally | Connects to the output circuit; completes the |
| | Open (NO) | circuit when the relay is activated. |
| | Contact | |
| 87a | Normally | Connects to the output circuit; provides a |
| | Closed (NC) | closed circuit when the relay is de-energized. |
| | Contact | |
| 85 | Coil Ground | Connects to ground, enabling current flow |
| | | through the coil when the relay is activated. |
| 86 | Coil | Connects to the power source or trigger signal |
| | Power/Trigger | to energize the coil and activate the relay. |

There are several types of relays commonly found in vehicles:
SPST (Single Pole Single Throw): 4 pins (30, 87, 85, 86). On/off control (e.g., headlights, accessories).
SPDT (Single Pole Double Throw): 5 pins (30, 87, 87a, 85, 86). Circuit switching (e.g., high/low beams).
4—Pin Relay: 30, 87, 85, 86. Basic control (e.g., auxiliary lights).
5—Pin Relay (Changeover): Adds 87a. Used for switching between outputs (e.g., power windows).
Micro Relay: 4/5 pins (30, 87, 87a, 85, 86). Compact (e.g., Electronic Control Unit (ECU) functions).
Mini Relay: 4/5 pins. Medium-current use (e.g., cooling fans, wipers).
Maxi Relay: 4/5 pins. High-current applications (e.g., starter motor).
Flasher Relay: 3/4 pins (49, 49a, 31, C). Controls turn signals/hazards.

There are several electromechanical relay sockets that are in popular use today. These include:
ISO Mini Relay Socket: The most prevalent type in standard vehicles, designed for relays with 4-pin or 5-pin configurations. These sockets are used for various critical vehicle systems like headlights, cooling fans, fuel pumps, and horn circuits.
ISO Micro Relay Socket: Common in newer vehicle models, these sockets accommodate smaller 4-pin or 5-pin relays. They are used in applications where space-saving is necessary, such as for power window and door lock controls.
ISO Maxi Relay Socket: These sockets are used for larger relays in vehicles that require higher current handling, such as starter motors and high-amperage auxiliary systems.
Bosch Type Relay Socket: A commonly used socket in vehicles for Bosch-style relays, which typically have a standard 4-pin or 5-pin layout. These sockets are often used in medium-current applications, including auxiliary lights and fuel systems.
Plug-in Relay Socket: These OEM sockets are designed for direct plug-in installation and replacement of standard 4-pin or 5-pin relays. They are widely used in vehicles for general functions like wiper motor controls and HVAC systems.

In addition to relays, cars include solenoids. A solenoid is an electromechanical device that converts electrical energy into linear motion. A coil of wire is wrapped around a metallic core, which becomes magnetized when an electric current passes through it. This magnetic field can cause movement in the metal core, creating a push or pull force that can be used to move components in various mechanisms. In cars, solenoids are commonly used for different functions, especially for controlling components that require precise on-and-off movements. These include starter motors, transmission controls, fuel injectors and exhaust gas recirculation (EGR) systems.

Solenoids and relays share several failure modes due to their similar reliance on electrical coils and mechanical components. Coil burnout or open circuits are common in both devices. In solenoids, excessive current, age, or repeated cycling can lead to overheating or coil breakage, preventing the solenoid from producing the magnetic field needed to move its core. Relays experience similar issues; when their coils burn out, they fail to generate the magnetic field required to move their contacts, resulting in the relay not closing or opening the circuit. Both devices, therefore, can completely fail to activate when their coils are damaged, often due to heat, which breaks down insulation and causes internal shorts or open circuits.

Mechanical wear or binding is another shared failure mode. High cycle counts or exposure to harsh conditions can cause solenoids to wear down, leading to sticking, binding, or complete mechanical failure. Dust, dirt, and lack of lubrication make these issues worse, reducing the solenoid's effectiveness. Relays also suffer mechanical wear, especially at their contact points, which can corrode, weld together, or experience contact bounce, impairing reliable connection. This mechanical degradation affects both devices, leading to partial activation, intermittent operation, or total failure over time.

Overheating is a significant risk for both solenoids and relays. A solenoid subjected to excessive current or continuous operation when only rated for pulses can overheat, melting internal components and damaging the coil. In relays, handling too much current causes overheating, resulting in melted or arcing contacts and accelerating contact wear. Overheating is a common issue in both devices when currents or duty cycles exceed their specifications, leading to coil burnout or other heat-related damage.

Power supply issues also affect both solenoids and relays. Voltage spikes, drops, or insufficient current prevent solenoids from generating enough force to actuate fully, causing incomplete or failed activations. Relays, too, are vulnerable to voltage fluctuations; insufficient voltage may stop the relay from closing, while spikes can lead to contact arcing or premature wear. Both devices require stable voltage and current to operate effectively, and inconsistent power supply can result in misfires, incomplete actions, or long-term stress-related damage.

Corrosion and environmental factors, like moisture, dust, or exposure to corrosive materials, are also common failure causes for solenoids and relays. For solenoids, environmental exposure can damage the moving parts or insulation, leading to malfunction. Relays face similar issues; without adequate sealing, moisture or dust can degrade the contacts, leading to poor electrical connections or total failure. In both cases, environmental factors, especially high moisture or dusty environments, compromise performance when devices lack sufficient protection.

Over time, magnetic materials in solenoids can degrade, especially with overuse, reducing magnetic strength and effectiveness. This loss of magnetism, or magnetic fatigue, is also possible in relays and can prevent the armature from fully pulling in, leading to weaker or inconsistent operation. As both devices rely on magnetism for actuation, degradation of magnetic materials directly affects their reliability and may result in inconsistent function or total operational loss over time. Understanding these shared failure modes helps diagnose issues, as both solenoids and relays are vulnerable to similar electrical and mechanical stresses.

Failing relays and solenoids in cars can significantly impact performance, safety, and reliability. Starter relays and solenoids work together to engage the engine; when they fail, starting the car can become unpredictable or impossible, potentially leaving drivers stranded. Transmission and fuel control failures from solenoids can lead to rough idling, stalling, or gear shift issues, increasing the risk of accidents, especially on highways or in heavy traffic.

Electrical overloads from failing relays can cause continuous power flow, leading to overheating, melted wires, or even electrical fires. Key components like headlights, windshield wipers, and the HVAC system also depend on relays to function reliably. Failures here can cause sudden losses in visibility or comfort controls, particularly dangerous in extreme weather or low-light conditions. ABS and traction systems can also suffer if related relays or solenoids malfunction, compromising braking and stability in emergencies.

Smaller components like door locks, fuel doors, and trunk latches also rely on solenoids, so failures may affect security or prevent access to essentials like fuel or spare tires. Solenoids and relays that control engine timing and other performance factors can lead to inconsistent power and poor acceleration if they malfunction, posing further risks during critical maneuvers. Environmental factors such as moisture, dust, and corrosion are common causes of relay and solenoid degradation, leading to sticking or loss of function over time. When relays or solenoids fail in the closed position, they can also drain the car battery, causing further inconvenience and potential downtime. Addressing symptoms early, like unusual sounds, erratic operation, or warning lights, is essential to maintain safety and prevent costly breakdowns associated with failing relays and solenoids.

### BRIEF SUMMARY

The present disclosure provides a system and method for identifying and testing vehicle electromechanical actuators, such as relays and solenoids, using onboard diagnostic (OBD) information. The system includes a processor, a network interface, a user interface, and a test socket for direct actuator testing. The processor receives OBD information, including diagnostic codes and vehicle identification data, to identify candidate actuators and determine potential issues. The identified actuator and its location are displayed on a user interface, along with relevant OBD information.

If the actuator can be tested in situ, the system displays instructions for performing the test. If in situ testing is not feasible, the system provides guidance for locating, removing, and inserting the actuator into the test socket. A test sequence is performed on the actuator, and results are displayed. If the actuator passes, reinstallation instructions are shown. If the actuator fails, replacement instructions are displayed. The processor may designate a specific test socket from a plurality of sockets and display wiring diagrams for efficient testing.

The system leverages vehicle identification information to tailor testing and display instructions specific to the actuator's configuration. It dynamically adjusts test sequences based on abnormal results, improving diagnostic accuracy. A computer-readable medium stores instructions for the method, enabling implementation across multiple platforms. The system simplifies testing processes, improves accuracy in identifying faults, and ensures compatibility with a wide range of vehicles and actuator types.

The subject disclosure provides example embodiments of a system and method for identifying and testing vehicle electromechanical actuators, such as relays and solenoids, leveraging onboard diagnostic (OBD) information and vehicle-specific data. The system comprises a processor, a network interface, a user interface with a display and input capabilities, and a test socket for direct actuator evaluation. It is designed to work in conjunction with a vehicle's OBD system, enabling streamlined identification, diagnostics, and testing of faulty actuators.

Upon receiving OBD information, which includes diagnostic codes and vehicle identification data, the processor analyzes the data to detect potential issues with a candidate actuator. The system identifies the specific actuator and displays its name, location within the vehicle, and relevant OBD information on the user interface. For actuators capable of in situ testing, the system provides step-by-step instructions for performing diagnostic tests directly within the vehicle. This includes visual guides and wiring diagrams to aid the user in executing the testing process accurately.

When an actuator cannot be tested in situ, the system displays detailed instructions for locating and removing the actuator from the vehicle. Once removed, the system guides the user on inserting the actuator into the appropriate test socket. The processor initiates a test sequence on the seated actuator and evaluates its performance. If the actuator passes, instructions for re-seating it in the vehicle are displayed. If the actuator fails, the system generates replacement instructions.

The system suitably incorporates features for enhanced accuracy and efficiency. Using the vehicle identification information obtained from the OBD system, the processor determines actuator properties and matches them to specific test protocols. For systems with multiple test sockets, the processor identifies the appropriate socket for the actuator and displays corresponding instructions. Wiring diagrams specific to the actuator type are shown to guide the user during testing.

To improve diagnostic precision, the system dynamically adjusts its test sequence based on real-time results. If abnormal results are detected during the initial sequence, the processor modifies the test sequence and re-runs it, ensuring comprehensive evaluation. The processor also determines test protocols linked to specific diagnostic codes, providing targeted assessments based on vehicle-specific fault information.

The system is further implemented as a method and a non-transitory computer-readable medium. The method involves receiving OBD data, identifying candidate actuators, determining test feasibility (in situ or removed), executing test sequences, and displaying results and next steps. The computer-readable medium stores instructions for performing these operations, allowing the invention to be deployed on multiple platforms.

This system significantly simplifies the testing process for vehicle actuators, providing tailored diagnostics, precise fault detection, and actionable guidance. It enhances maintenance efficiency by integrating OBD information, vehicle-specific data, and user-friendly interfaces to address actuator issues effectively.

### BRIEF DESCRIPTION OF THE DRAWINGS

These and other features and advantages of the various embodiments disclosed herein will be better understood with respect to the following description and drawings, in which:

FIG. 1 illustrates an example embodiment of a system for inspection of car relays using a scan tool;

FIG. 2 is a flowchart of an example embodiment of a system for inspection of car electromagnetic actuators using a scan tool;

FIG. 3 is a flowchart of an example embodiment of an in-vehicle electromagnetic actuator test;

FIG. 4 is a flowchart of an example embodiment of a tester implemented electronic actuator test;

FIGS. 5A and 5B are flowcharts of an example embodiment of use case for testing and diagnosing an electromagnetic actuator;

FIG. 6 illustrates an example embodiment of a user interface display in a relay testing sequence showing active diagnostic testing codes and associated explanations;

FIG. 7 illustrates an example embodiment of a user interface display in a relay testing sequence showing a relay selected for testing;

FIG. 8 illustrates an example embodiment of a user interface display in a relay testing sequence showing a diagram of a relay for testing; and

FIG. 9 illustrates an example embodiment of a user interface display in a relay testing sequence showing instructions for in situ vehicle relay testing.

### DETAILED DESCRIPTION

The detailed description set forth below in connection with the appended drawings is intended as a description of certain embodiments of a vehicle diagnostic system and related method, and is not intended to represent the only forms that may be developed or utilized. The description sets forth the various structure and/or functions in connection with the illustrated embodiments, but it is to be understood, however, that the same or equivalent structure and/or functions may be accomplished by different embodiments that are also intended to be encompassed within the scope of the present disclosure. It is further understood that the use of relational terms such as first and second, and the like are used solely to distinguish one entity from another without necessarily requiring or implying any actual such relationship or order between such entities.

Example embodiments herein include a system and method to determine whether failed or failing relays or solenoids are present in a vehicle, isolate one or more for testing, assist in locating a potentially problematic part and assist in testing that part. While example embodiments are directed to relay issues, it is to be appreciated that the systems and methods herein include any suitable electromechanical actuator, including but not limited to relays and solenoids.

Vehicle On-Board Diagnostic Systems (OBDs) are electronic systems in vehicles that monitor and regulate various engine and emission control components to ensure optimal performance and compliance with environmental standards. Originally developed in the 1980s, OBD systems were designed to help technicians diagnose issues by providing access to information from the vehicle's control modules. OBD-I (On-Board Diagnostics I) was a first generation OBD system implemented in vehicles. It was introduced primarily in the 1980s and became mandatory in the United States in 1991 by the California Air Resources Board (CARB) to monitor and control vehicle emissions. However, OBD-I was not a unified or fully standardized system in the way that OBD-II is today. The introduction of the OBD-II standard in 1996 in the United States made it mandatory for all cars to have a universal diagnostic system that could communicate standardized codes, known as Diagnostic Trouble Codes (DTCs), to identify specific malfunctions. OBD systems monitor the engine, transmission, emissions controls, and other crucial systems, and they can alert the driver with a “Check Engine” or similar warning light when a fault is detected. This technology allows mechanics and vehicle owners to diagnose and address problems quickly using an OBD scanner, improving vehicle reliability, safety, and environmental performance.

Standard DTCs associated with relay issues often fall under the P, B, and C code categories, which relate to the powertrain, body, and chassis systems respectively. Here are some of the common DTCs associated with relay issues:
P0685-P0691 (ECM/PCM Relay Control Circuit): These codes indicate problems with the powertrain control module (PCM) or engine control module (ECM) relay circuits. They typically refer to the ECM or PCM's inability to control the relay properly, often pointing to a faulty relay, wiring issue, or internal failure.
P0480-P0483 (Cooling Fan Relay Circuits): These codes are associated with the cooling fan relay or the fan's control circuit. A faulty relay, open or shorted circuit, or a failed fan control module could trigger these codes.
P0230-P0233 (Fuel Pump Relay Circuit): These codes indicate an issue with the fuel pump relay or its control circuit. Problems such as a faulty relay, wiring problems, or PCM issues could cause these codes to appear.
B1370-B1374 (Various Body Control Module Relay Faults): These codes are associated with relays controlling body-related systems, such as power windows, door locks, or interior lighting. Issues might stem from faulty relays, BCM malfunctions, or wiring issues.
C1032-C1036 (Chassis System Relay Issues): These codes indicate problems with relays controlling chassis-related functions, such as ABS or traction control systems.

OEM-specific DTCs for mechanical relays offer detailed information tailored to each manufacturer's design and systems. These codes go beyond standard OBD-II codes, targeting specific components or subsystems in a vehicle that rely on mechanical relays. For instance, OEM DTCs often address relay control circuits, such as Ford's B1342 or B1343, which indicate faults in circuits like those controlling interior lighting or fuel pumps. Toyota's C1253 highlights relay failures in anti-lock braking or traction control systems, while GM's U1000 series codes sometimes point to communication issues related to relay control modules or power distribution centers.

Powertrain-related relay failures are also indicated by specific codes. GM and Ford's P2610 refers to relay circuit issues in the ECM/PCM, and Volkswagen and Audi's P068A might indicate a main relay malfunction or problems with power shutdown timing. For body systems, OEM DTCs like Toyota's B1425 identify faults in air conditioning relay circuits within the Body Control Module, and Ford's B2430 can relate to issues with relay circuits managing heated seats or other comfort features.

OEMs frequently assign unique codes for auxiliary or accessory relay problems. Chrysler's C1035 could signal a relay fault controlling a specific chassis component like suspension or stability control, while Mercedes-Benz's U0146 indicates a loss of communication with relay control modules or submodules responsible for features like adaptive lighting or motorized components. These codes can be accessed using manufacturer-specific diagnostic tools or software such as Toyota Techstream, Ford IDS, BMW ISTA, or GM's GDS2.

Additional information is available from an OBD port in addition to DTC codes. Real-time data and snapshot data from an OBD-II port can offer valuable insights into potential relay issues in a vehicle. The OBD-II system, while primarily focused on engine and emissions-related monitoring, also captures information from control modules that can indicate relay malfunctions. For instance, live voltage readings from various circuits and sensors can help detect whether a relay is failing to provide consistent voltage or if an abnormal current draw is occurring. Additionally, real-time data can show relay activation status, which indicates whether critical relays such as those controlling the fuel pump, cooling fans, or HVAC blower motor are being properly commanded to open or close. The ECM or BCM can report whether the relay's activation signal matches expected operations. This is useful when checking component state information, which can highlight issues if data shows that components reliant on relays, like cooling fans or AC compressors, are not activating as expected. Temperature and pressure data from sensors, such as the engine coolant temperature sensor or the transmission fluid temperature sensor, may reveal abnormal conditions, indicating that a relay controlling a fan or pump is malfunctioning.

Snapshot or real-time data, captured after a DTC is triggered, records the vehicle's operating conditions. This data might include relay command status, voltage levels, and other parameters relevant to the malfunction. For example, if a cooling fan-related DTC is triggered, freeze frame data could reveal if the relay was commanded to activate, along with details like coolant temperature and fan speed. Voltage and ground readings at the time a fault code was set can also indicate a problem with the relay affecting power or ground connections to a component. For relays controlling components via pulse-width modulation (PWM), snapshot data can capture duty cycle percentages or load values, which could indicate relay or circuit issues if they are abnormal. For more information regarding the retrieval and analysis of vehicle data, please refer to the following U.S patents and published patent applications, owned by Innova Electronic Corporation, which is also the owner of the present disclosure: U.S. Pat. No. 6,807,469, entitled AUTO DIAGNOSTIC METHOD AND DEVICE, U.S. Pat. No. 6,925,368, entitled AUTO DIAGNOSTIC METHOD AND DEVICE, U.S. Pat. No. 7,620,484, entitled AUTOMOTIVE MOBILE DIAGNOSTICS, U.S. Pat. No. 8,019,503, entitled AUTOMOTIVE DIAGNOSTIC AND REMEDIAL PROCESS, U.S. Pat. No. 8,370,018, entitled AUTOMOTIVE DIAGNOSTIC PROCESS, U.S. Pat. No. 8,909,416, entitled HANDHELD SCAN TOOL WITH FIELD SOLUTION CAPABILITY, U.S. Pat. No. 9,026,400, entitled DIAGNOSTIC PROCESS FOR HOME ELECTRONIC DEVICES, U.S. Pat. No. 9,177,428, entitled PREDICTIVE DIAGNOSTIC METHOD, U.S. Pat. No. 9,646,432, entitled HAND HELD DATA RETRIEVAL DEVICE WITH FIXED SOLUTION CAPABILITY, U.S. Pat. No. 10,643,403, entitled PREDICTIVE DIAGNOSTIC METHOD AND SYSTEM, U.S. Pat. No. 11,068,560, entitled METHOD OF PROCESSING VEHICLE DIAGNOSTIC DATA, U.S. Pat. No. 11,270,529, entitled SYSTEM AND METHOD FOR PROACTIVE VEHICLE DIAGNOSIS AND OPERATIONAL ALERT, U.S. Patent Application Pub. No. 11,158,141, entitled SYSTEM AND METHOD FOR PROACTIVE VEHICLE DIAGNOSIS AND OPERATIONAL ALERT, U.S. Patent Application Ser. No. 12,112,587 entitled SYSTEM AND METHOD FOR GUIDED VEHICLE DIAGNOSTICS, U.S. Patent Application Ser. No. 11,915,534 entitled VEHICLE DIAGNOSTICS WITH INTELLIGENT COMMUNICATION INTERFACE, U.S. Pat. No. 11,625,962, entitled SYSTEM, METHOD, AND COMPUTER PROGRAM PRODUCT FOR PROVIDING APPLICATION-BASED ASSISTANCE WITH VEHICLE EMISSION TEST COMPLIANCE, the entire contents of each of which is expressly incorporated herein by reference.

Furthermore, the BCM or ECM monitors voltage levels in various relay circuits and can detect problems with relay control circuits or communication with relay-controlled modules. In some advanced vehicles, relays with built-in feedback circuits report their status to control modules, providing real-time data to show if the relay is open, closed, or stuck. Technicians can use OBD-II scanners to view live data streams and snapshot data, focusing on parameters like voltage, current, relay command status, and sensor readings. This helps correlate data with vehicle symptoms to identify if a relay is not engaging or disengaging properly. Analyzing data alongside triggered DTCs enables technicians to pinpoint the root cause of an issue, whether it's a relay fault, corroded terminals, or wiring problems. Real-time and snapshot data from the OBD-II system thus offer a detailed view of relay and circuit functionality, aiding in efficient diagnosis and resolution of relay-related problems.

DTC codes and snapshot data is suitably obtained from an OBD port by diagnostic device issuing one or more mode commands and one or more Parameter Identification Codes (PIDs). Modes and PIDs are components of the OBD-II diagnostic system that allow a diagnostic testing device to communicate with a vehicle's on-board computer. Modes define the type of action or data being requested, such as retrieving real-time sensor information, stored fault codes, or vehicle details. For example, Mode 01 is used to request current data like engine RPM or battery voltage, while Mode 03 is used to retrieve stored (DTCs). Within each mode, PIDs (Parameter Identification Codes) specify the exact data point to be accessed. A diagnostic tester first selects a mode to indicate the type of information needed, and then issues a corresponding PID to obtain specific information within that mode. This combination of modes and PIDs allows the device to effectively gather targeted real-time data and diagnostic information from the vehicle's systems.

Standard modes and PIDs are defined by the OBD-II protocol (SAE J1979) and are common across all OBD-II-compliant vehicles, OEM PIDs provide additional data points specific to each vehicle manufacturer's design and architecture. These PIDs allow access to more in-depth diagnostics, monitoring, and system performance information that is unique to a particular make and model of a vehicle.

To obtain DTCs and data related to relay issues from an OBD-II system, specific Parameter IDs (PIDs) and OBD-II modes are used. Example modes for securing relay information are as follows:
Mode 03: Request DTCs retrieves stored DTCs from control modules like the ECM, TCM, and BCM, displaying active or pending relay-related codes.
Mode 07: Request Pending DTCs identifies pending DTCs for intermittent relay issues not yet confirmed as permanent faults.
Mode 02: Freeze Frame Data provides a snapshot of vehicle conditions (e.g., RPM, coolant temperature, sensor voltage) at the moment a DTC was triggered, aiding in diagnosing relay circuit malfunctions.
Mode 01: Real-Time Data uses PIDs to access live readings (e.g., Battery Voltage PID 42, Engine Coolant Temperature PID 05, relay status PIDs). It shows voltage, relay activation states, and commanded actuator states for diagnostics.
Mode 09: Vehicle Information retrieves the VIN, ECU software version, and calibration data to verify vehicle specifics, ensuring correct relay circuit analysis.
Mode 06: On-Board Monitoring gives detailed results for specific components, including voltage and resistance checks on relay circuits. It shows tests for systems like cooling fan and fuel pump relays, confirming if they operate within parameters.

Example embodiments herein provide for diagnosing potential relay issues with DTC information, identifying one or more relays in need of testing, assisting a user in locating these relays for testing, such as by removing them and plugging them into a tester. Relay-related DTCs can help identify specific relays that need to be extracted and tested by providing detailed information about the affected circuits or systems. These codes often indicate the particular circuit or system with a fault, such as P0480 for a cooling fan relay circuit issue or P0230 for a fuel pump relay problem. Sources of information such the vehicle's service manual allow for assistance in providing instructions to locate a relay that controls an indicated component. Many DTCs also refer to relay positions or numbers within a module or fuse box, like P0685 indicating an ECM/PCM relay circuit issue. Provided information suitably lists the specific relay labeled as “ECM Relay 1” or something similar, helping to pinpoint the relay's location.

OEM-specific DTCs often associate relays with specific components, like B1425 identifying the air conditioning relay circuit, which directs technicians to the AC relay for inspection. Similarly, DTCs reference subsystems and the control modules associated with them, such as the BCM or the PCM. If the DTC indicates an issue in a subsystem managed by one of these modules, such as B2430 for heated seat control, technicians can consult electrical diagrams to find which relays are governed by that module. Vehicle service manuals provide relay layouts and cross-references for DTCs, allowing technicians to match codes like P0691 to the specific relay in the cooling fan circuit.

In more modern vehicles, DTCs may indicate communication issues between control modules and relays, such as U0146 pointing to lost communication with a relay-controlled module. This can direct attention to the relays associated with that module. Once the DTC identifies a particular circuit or component, technicians can use the vehicle's electrical schematics to precisely locate the relevant relay. Testing involves extracting the relay from the panel or fuse box and checking its functionality with a multimeter or relay tester. If the relay fails, replacing it can resolve the issue indicated by the DTC.

Certain relays may be testable without having to remove them from a vehicle. Relays that can commonly be tested in-car include those for the fuel pump, horn, headlights, cooling fan, starter, and AC compressor. A relay that can be tested while still installed in a car generally has specific characteristics. It should have an accessible pin configuration with exposed terminals that allow for probing with a multimeter, typically including common pin numbers like 85, 86, 30, 87, and 87a. These relays often adhere to standard automotive configurations, making them straightforward to test without removal. They are typically involved in defined roles within vehicle systems such as fuel pumps, cooling fans, headlights, or A/C compressors, which allows their operation to be verified by activating the corresponding system. The presence of identifiable coil pins (85 and 86) and power or load terminals (30, 87, and possibly 87a) facilitates in situ testing for voltage, continuity, and activation. Relays that audibly click when engaged are easier to diagnose as the sound confirms the coil's function. Relays that are not fully sealed or have seals that don't hinder electrical probing are also simpler to test while in place. Most automotive relays operate at a standard 12V, matching the vehicle's electrical system and enabling them to be tested using typical tools for voltage and continuity checks.

A presence of certain DTCs can indicate that in situ testing is an available option:
P0685-ECM/PCM Power Relay Control Circuit/Open: Indicates a potential faulty relay or wiring issue in the control circuit.
P0686-ECM/PCM Power Relay Control Circuit Low: Insufficient voltage in the control circuit, possibly due to a failing relay or poor connections.
P0687-ECM/PCM Power Relay Control Circuit High: Higher-than-expected voltage, suggesting a malfunctioning relay or electrical fault.
P0690-ECM/PCM Power Relay Sense Circuit High: High voltage detected, indicating a stuck relay or circuit fault.
P0691/P0692-Fan Relay Control Circuit Low/High: Issues with the cooling fan relay or its control circuit.
P0480-Cooling Fan 1 Control Circuit Malfunction: Potential problem with the cooling fan relay or wiring.
P0481-Cooling Fan 2 Control Circuit Malfunction: Issue with the second cooling fan's control circuit or relay.
P0230-Fuel Pump Primary Circuit Malfunction: Suggests a faulty fuel pump relay or issues in the circuit wiring.
P0251—Injection Pump Fuel Metering Control “A” Circuit Malfunction: May indicate relay or circuit issues in fuel system control.
P0628—Fuel Pump Control Circuit Low: Low voltage in the fuel pump relay/control circuit.
P0629—Fuel Pump Control Circuit High: High voltage in the control circuit, possibly due to a faulty relay.
P0645—A/C Clutch Relay Control Circuit: Indicates an issue with the A/C clutch relay, testable while installed.
U0100—Lost Communication with ECM/PCM: Could be related to relay issues affecting the power supply to the ECM/PCM.

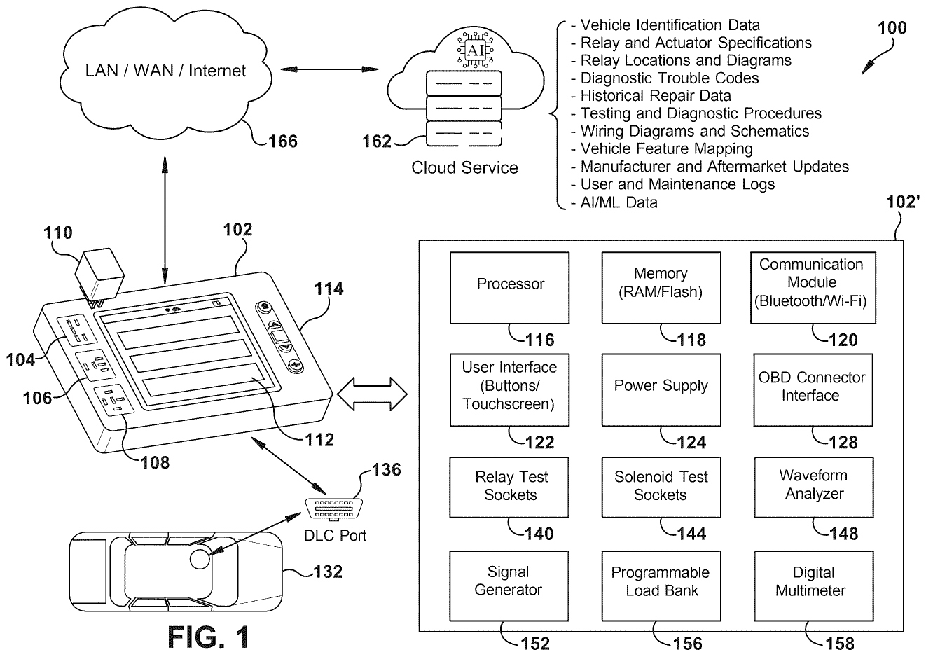

FIG. 1 illustrates an example embodiment of a system 100 for inspection of car relays using a scan tool 102 (e.g., a data acquisition and transfer device (DAT)), illustrated by functional block diagram 102′. Scan tool 102 includes one or more electromechanical actuator test sockets, illustrated by test sockets 104, 106 and 108. In the illustrated example, test socket 104 is configured to receive relay 110 for testing. Scan tool 102 further includes touchscreen 112 and control buttons or switches 114.

Scan tool 102 includes processor 116 and associated volatile or non-volatile data storage, such as memory 118. Data communication is via communication module 120, suitably comprised of any wireless or wired data communication path, such as Bluetooth or Wi-Fi. User interface 122 is suitably comprised touchscreen 112 and associated selection buttons or switches 114. Power supply 124 is comprised of any suitable power source, such as via an external power connection, or an internal storage such as a battery, which may be rechargeable. An OBD data interface 128 provides data communication with vehicle 132, suitably through its data link connector (DLC) port 136, facilitating communication of DTC data and live data, such via a vehicle engine control module (ECM). It is contemplated that data communication between the OBD data interface 128 and the DLC port 136 may be via wired communication or wireless communication.

Also included in scan tool 102 are one or more relay test sockets 140, such as test sockets 104, 106 and 108, and one or more solenoid test sockets 144 which are configured to receive components for testing after removal from the vehicle.

Testing functionally is provided by waveform analyzer 148, signal generator 152, programmable load bank 156 and digital multimeter 158. Waveform analyzer 148 captures and visualizes electrical waveforms in real-time, enabling detailed analysis of relay and solenoid behavior during switching events. It identifies anomalies in actuation signals, such as timing issues, signal noise, and contact arcing, while measuring key parameters like rise and fall times, frequency, duty cycle, voltage, and current transients. This facilitates troubleshooting signal integrity issues and verifying proper actuator response to control signals, as well as detecting transient behaviors that might not be evident in static tests.

Signal generator 152 produces controlled electrical signals to simulate vehicle control commands or operating conditions. It suitably generates DC voltages, pulse-width modulated (PWM) signals, and other waveforms with adjustable amplitude, frequency, duty cycle, and signal shape. This allows for the simulation of ECU signals, testing actuator responses to varying inputs, and replacing control units in isolated diagnostic setups.

Programmable load bank 156 simulates real-world electrical loads, testing relays and solenoids under realistic conditions. It can replicate resistive, inductive, and capacitive loads with programmable values to match specific scenarios. The load bank monitors voltage drops, current, and the relay's or solenoid's performance under varying loads. This enables stress testing, verifying voltage and current handling capabilities, and diagnosing contact wear, overheating, or performance degradation.

Digital multimeter 158 provides precise measurements of electrical parameters like voltage, current, resistance, continuity, and diode functionality. It is used for basic electrical diagnostics, verifying relay coil resistance, confirming input and output conditions, and detecting open or short circuits. By integrating these tools, the tester can comprehensively analyze both dynamic and static characteristics of relays and solenoids, ensuring their functionality and reliability.

Testing is suitably done in conjunction with cloud service 162, in data communication with tester 104 via network cloud 166. Network cloud 166 is suitably comprised of any wired or wireless connection that may include a local area network (LAN), a wide area network (WAN) which may comprise the Internet, or any suitable combination thereof.

Cloud server integration facilitates multiple functions to enhance the testing and repair process for relays and other components. It suitably provides a comprehensive database for VIN decoding, enabling the retrieval of detailed vehicle-specific information such as the make, model, year, engine type, and trim level. This information helps pinpoint the exact specifications and locations of relays and other actuators within a vehicle. The cloud server suitably stores diagrams and wiring schematics, including relay box layouts and pin configurations, which assist in identifying the correct relay and understanding its role within the vehicle's system.

Cloud server 162 stores DTCs and their descriptions, correlating them with potential relay or circuit issues. This facilitates providing detailed instructions for testing and troubleshooting components based on these codes, providing targeted workflows for addressing faults. Additionally, the server suitably hosts historical repair data, highlighting common relay failures, frequent replacement patterns, and solutions that have proven effective for specific vehicle models. This data can be used to predict maintenance needs or offer repair recommendations.

Cloud server 162 also suitably provides real-time and OEM-specific live data, allowing monitoring of relay behavior and assess performance under various operating conditions. The server suitably stores and retrieves manufacturer-specific updates, technical service bulletins (TSBs), and recall information, ensuring the most current information. It also facilitates access to repair guides, replacement procedures, and sourcing details for OEM and aftermarket parts.

With AI and machine learning, the cloud server analyzes test results, compares them with historical patterns, and suggests probable causes for anomalies. It also identifies subtle issues that may not be apparent from traditional diagnostics, offering enhanced accuracy. Through continuous updates and global data integration, the cloud server improves diagnostic capabilities, providing an ecosystem where vehicle-specific and aggregate data work together to streamline repairs and optimize system performance.

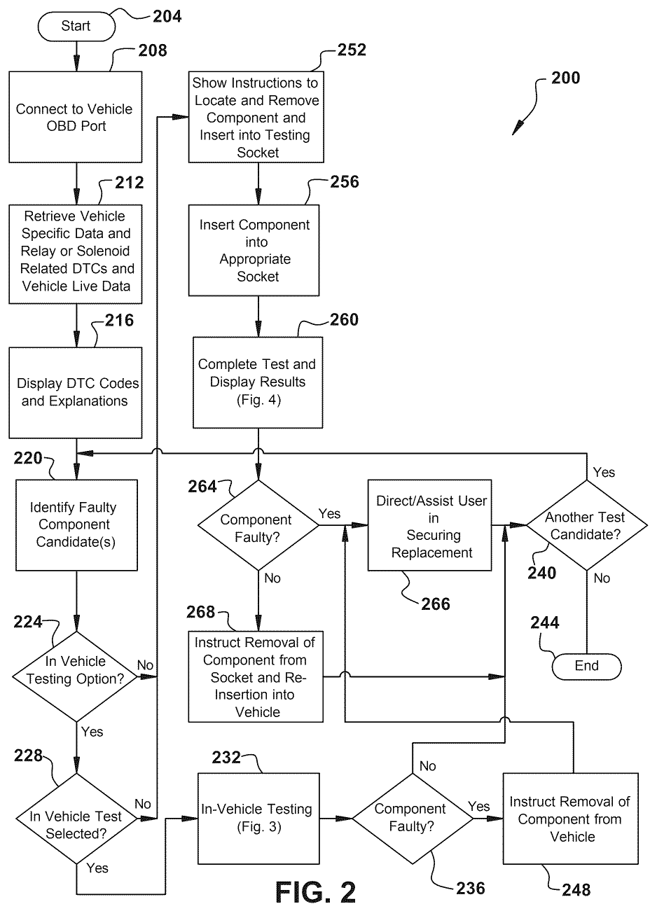

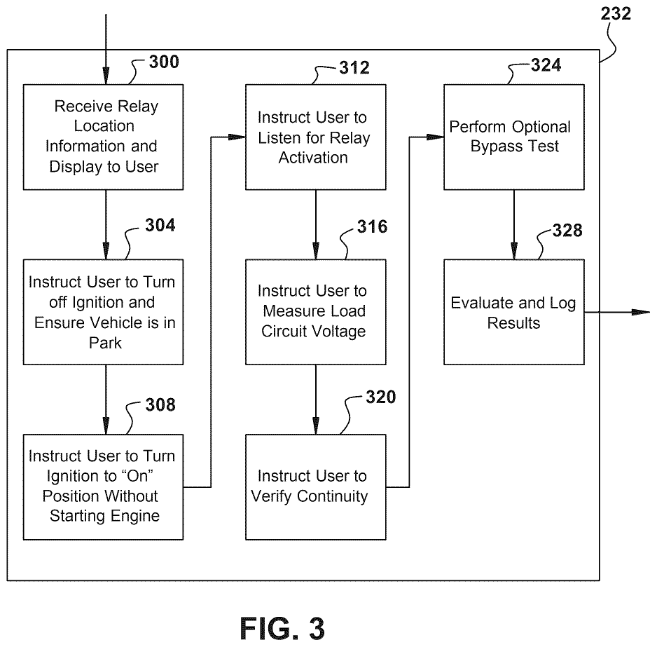

FIG. 2 illustrates a flowchart 200 of an example embodiment of a system for inspection of car electromagnetic actuators using a scan tool. The system commences at block 204 and proceeds to block 208 where a data connection is made to a vehicle OBD port. Once connected, vehicle specific data and OBD data, such as DTC codes, OEM DTC codes, live data, freeze frame data, and OEM live data are retrieved at block 212. OBD data, such as DTC codes and their associated explanations, are shown on the tester display at block 216. One or more faulty component candidates are identified at block 220, and a determination is made as to whether an identified component is available for in-vehicle testing at block 224. If so, and if in-vehicle testing is selected at block 224, an in-vehicle testing is initiated at block 232, described in detail below in connection with FIG. 3. A determination is made at block 236 whether the in-vehicle tested component was faulty. If not, a determination is made at block 240 as to whether another component is a candidate for testing. If not, the process ends at block 244, if so, the process returns to block 220. If the component is determined to be faulty at block 236, instructions for removal are shown at block 248 and the process proceeds to block 266 to proceed as detailed above.

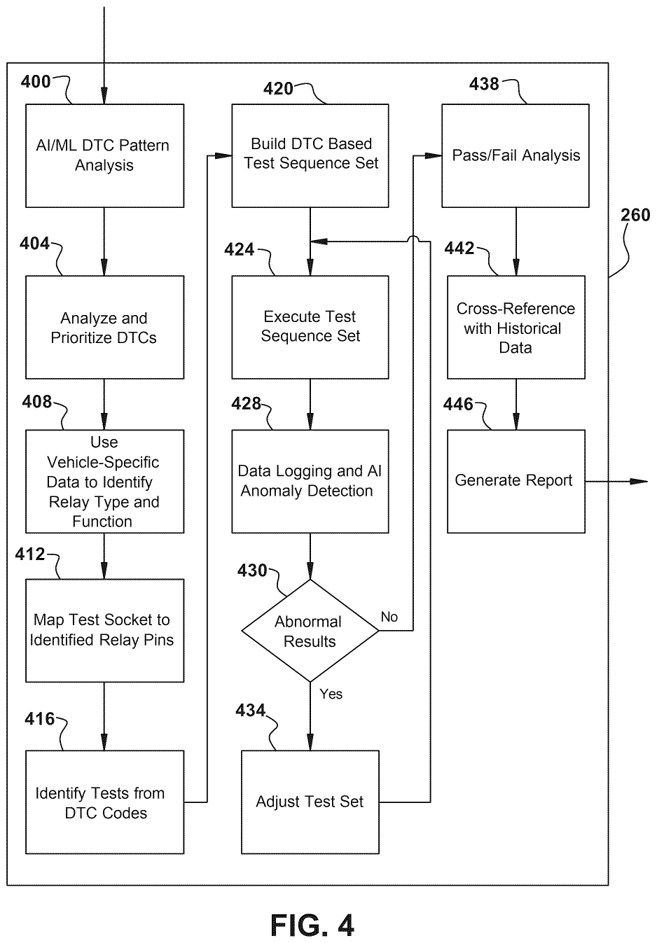

If in-vehicle testing is not available from block 224, or has not been selected at block 228, the process proceeds to block 252 where instructions to locate the component, remove it and insert it into a test socket is shown. The component is inserted into the test socket at block 256, and a testing sequence is performed on it at block 260. Details of the testing sequence are provided below in connection with FIG. 4. If a component is determined to be faulty at block 264, the process progresses to block 266 where user assistance is displayed for securing a replacement, then proceeding block 240 as detailed above. If the component is not faulty, instructions for removal of the component from the testing socket and reinsertion into the vehicle are shown at block 268 before progressing to block 240 to proceed as detailed above.

FIG. 3 is a flowchart of an example embodiment of an in-vehicle test suitably used in conjunction with block 232 from FIG. 2. Relay location information is received and shown to the user at block 300. The user is instructed to turn off the ignition and ensure that the vehicle is in park at block 304. The user is then instructed to turn the ignition to the “on” or accessory position without starting the engine at block 308. The user is instructed to listen for relay activation at block 312, and to measure load circuit voltage at block 316. Displayed instructions and diagrams may direct positioning and reading a voltmeter, or other self-test device. Instructions for a user to verify continuity are shown at block 320. Instructions for an optional bypass test may be shown at block 324. Results are evaluated and logged at block 328 wherein the self-test sequence is completed.

The system is suitably further configured to include one or more autonomous functionalities to enhance diagnostic, testing, and repair recommendation capabilities for vehicle electromechanical actuators. As used herein, autonomous may refer to functionalities that are implemented in response to a triggering event, wherein the implementation of such functionalities may occur independent of user intervention. Along these lines, any action associated with the diagnostic process may be a trigger for any or all subsequent actions. Such autonomous actions can improve efficiency, reduce manual intervention, and ensure more accurate diagnostics under various conditions. For instance, in the in-vehicle testing mode, at block 312, the scan tool 102 may establish direct communication with the vehicle via the OBD port. In response to a determination or selection that in-vehicle testing is appropriate, the tool may automatically send a relevant active test command (e.g., to check live data corresponding to each test condition) to activate the relay or solenoid being testing and will instruct the user to listen for relay activation at the same time (instructing the user to further check if needed). Once complete, the tool may evaluate and display the test results.

The processor is suitably configured to autonomously monitor diagnostic data trends over time, including resistance, current draw, and operational frequency of electromechanical actuators. By analyzing these trends, the system can predict potential failures before they occur. For example, if a cooling fan relay demonstrates increasing resistance during operation, the system can alert the user to a likely impending failure and recommend proactive replacement.

In scenarios where multiple diagnostic trouble codes (DTCs) or fault conditions are detected, the processor suitably autonomously prioritizes diagnostic and testing actions based on contextual factors. These factors may include the severity of the detected fault, the criticality of the actuator to vehicle operation, and live data discrepancies indicating immediate issues. For instance, if a starter relay and an HVAC blower motor relay both present fault conditions, the system will prioritize diagnostics of the starter relay due to its importance in enabling vehicle operation.

The system also incorporates machine learning algorithms that enable it to refine its diagnostic processes over time. By analyzing historical diagnostic and repair data, including the outcomes of past tests, the processor can optimize testing parameters for specific vehicle models or actuator types. This learning capability allows the system to adapt to evolving vehicle technologies and user behaviors, ensuring continued diagnostic accuracy and relevance.

To improve fault isolation in complex systems, the processor suitably autonomously performs iterative diagnostics. When initial tests suggest multiple potential causes for a failure, the system sequentially or concurrently tests related subsystems and components to identify the exact source of the issue. For example, if live data indicates a fault in a fuel pump relay circuit, the processor may also test the associated wiring, fuse, and fuel pump actuator to pinpoint the problem.

The system is also suitably configured to autonomously retrieve and analyze vehicle-specific information, including actuator specifications, wiring diagrams, and relay box layouts, based on the vehicle identification number (VIN). Upon detecting a faulty actuator, the processor autonomously verifies the compatibility of replacement parts. By comparing specifications retrieved via the VIN to the installed component, the system ensures that the replacement meets the vehicle's operational requirements.

The processor also suitably autonomously adjusts its testing protocols based on environmental factors detected by the vehicle's sensors, such as ambient temperature, battery voltage, or load conditions. For example, during cold weather, the system modifies its relay thermal testing thresholds to account for the increased resistance often observed in such conditions. Similarly, the system adjusts its parameters for vehicles operating in high-temperature environments to prevent false positives caused by temporary thermal stress.

The system suitably autonomously calibrates actuators after installation to ensure optimal performance. For example, following the replacement of a solenoid, the processor initiates a calibration process to align the actuator's operation with manufacturer specifications. This calibration may include adjusting timing, pressure, or other parameters as necessary.

To improve safety, the processor suitably autonomously enforces safety protocols during diagnostic and testing processes. If hazardous conditions are detected, such as live circuits during actuator removal, the system generates alerts and provides safety instructions to the user. For example, the system may display warnings to disconnect the vehicle battery before handling high-current relays. Additionally, if testing conditions are deemed unsafe due to live data readings (e.g., overheating components), the system will automatically suspend testing and provide corrective recommendations.

For fleet or multi-vehicle environments, the processor can suitably autonomously analyze data across multiple vehicles to identify systemic issues. For instance, if several vehicles in a fleet show patterns of relay failure under specific conditions, the system can recommend preemptive maintenance or part replacement to prevent widespread operational disruptions.

The system suitably autonomously initiates and integrates updates to its diagnostic database and testing protocols upon detecting new vehicle models, actuator types, or manufacturer updates. These updates ensure compatibility with evolving vehicle technologies and enable the system to address new diagnostic challenges without manual intervention.

By incorporating such autonomous functionalities, the system significantly reduces manual effort, enhances diagnostic precision, and provides a robust foundation for efficient vehicle maintenance and repair. These features are designed to operate seamlessly within the existing architecture, leveraging the onboard diagnostic system, VIN-based data retrieval.

FIG. 4 is a flowchart of an example embodiment of a component testing by the tester device itself, suitably used in conjunction with block 260 of FIG. 2. An AI/ML pattern analysis of available information is made at block 400, and OBD information, such as DTCs, are analyzed and prioritized at block 404. Vehicle specific information is used at block 408 to identify a relay type and function. The test socket is then mapped to identify relay pins at block 412. Tests are identified at block 416 from OBD data, such as DTC codes. A test sequence corresponding to the identified tests is constructed at block 420 and executed at block 424. Result processing and data logging is completed at block 428. If it is determined that abnormal results are found at block 430, the test set is adjusted at block 434 before returning to block 424. If no abnormal results are found, a pass/fail analysis is completed at block 438. A cross-reference with historical data is completed at block 442 and a report is generated at block 446, after which the test is completed.

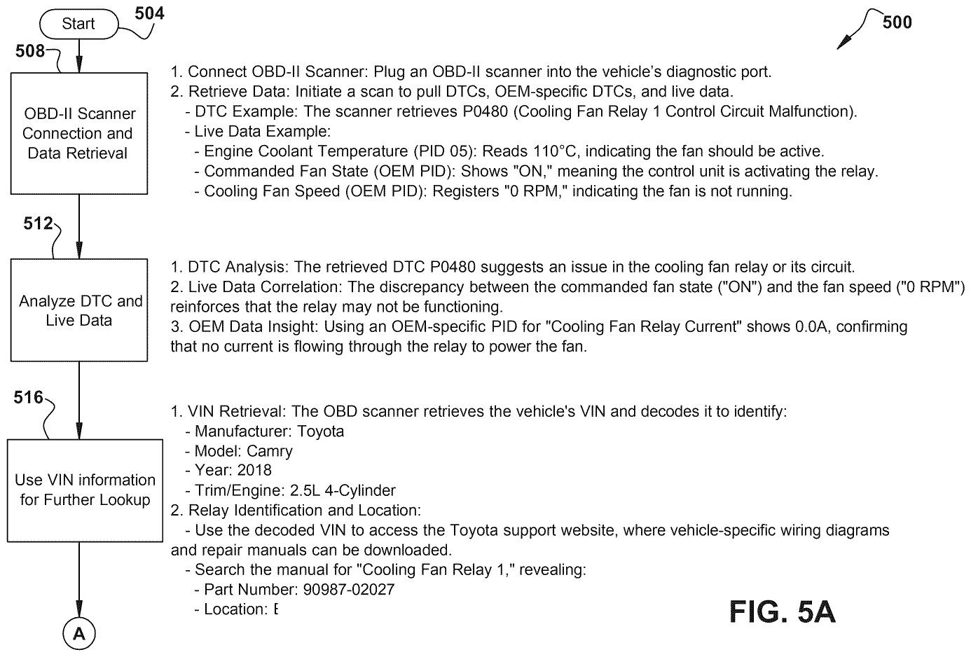

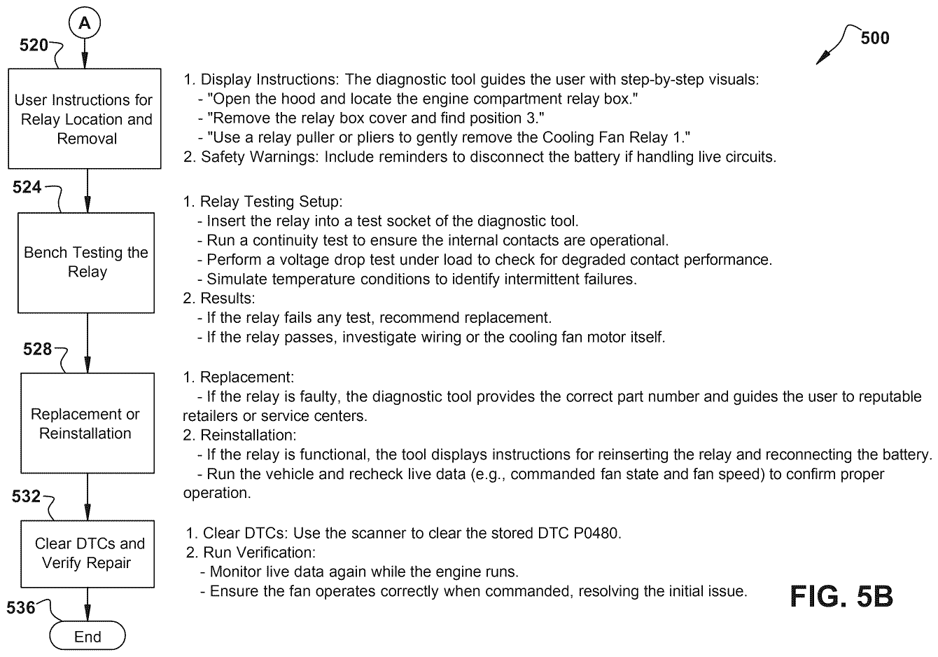

FIGS. 5A and 5B illustrate flowchart 500 of an example embodiment of use case for testing and diagnosing an electromagnetic actuator, such as a relay. The process begins at block 504 and proceeds to block 508 with plugging an OBD-II scanner into a vehicle's diagnostic port. This initiates a scan to retrieve DTCs, OEM-specific DTCs, and live data. For example, the scanner may retrieve P0480, indicating a Cooling Fan Relay 1 Control Circuit Malfunction. Live data might show an engine coolant temperature (PID 05) reading of 110° C., signaling that the fan should be active. Additional data, such as the commanded fan state (OEM PID) showing “ON” and cooling fan speed (OEM PID) registering “0 RPM,” further confirm the fan is not functioning as expected.

The resulting information is then analyzed at block 512. This information reveals that the DTC P0480 suggests an issue in the cooling fan relay or its circuit. The discrepancy between the commanded fan state (“ON”) and the actual fan speed (“0 RPM”) supports the likelihood of a malfunctioning relay. OEM-specific data, such as “Cooling Fan Relay Current” showing 0.0A, confirms that no current is flowing through the relay to power the fan.

Next, at block 516, the vehicle's VIN is retrieved from scanner information and it is decoded to gather specific information, such as the manufacturer (Toyota), model (Camry), year (2018), and engine type (2.5 L 4-Cylinder). The VIN is used to access the Toyota support website for vehicle-specific wiring diagrams and repair manuals. A search for “Cooling Fan Relay 1,” reveals the part number (90987-02027) and its location in the engine compartment relay box, position 3.

Next, at block 520, the diagnostic tool provides step-by-step instructions for locating and removing the relay. The user is guided to open the hood, locate the engine compartment relay box, remove its cover, and find position 3. Using a relay puller or pliers, the Cooling Fan Relay 1 can be gently removed. Safety warnings remind users to disconnect the battery when handling live circuits.

Once removed, the relay should be bench-tested at block 524. The relay is inserted into an appropriate diagnostic tool test socket a continuity test is run to check the operational status of the internal contacts. A voltage drop test under load is performed to identify degraded performance and detect intermittent failures. If the relay fails this test, it should be replaced. If it passes, further investigation of the wiring or cooling fan motor may be necessary.

Block 528 directs replacement of a faulty relay or reinstallation of a functioning relay. For a faulty relay, the diagnostic tool provides the correct part number and directs the user to reputable retailers or service centers for replacement. If the relay is functional, the tool gives instructions for reinserting it into the vehicle and reconnecting the battery. After reinstallation, the vehicle should be run, and live data rechecked to confirm proper operation, including verifying that the commanded fan state matches the fan speed.

Next, at block 532 the scanner clears the stored DTC P0480 and verifies the repair by monitoring live data while the engine is running. This ensures that the fan operates correctly when commanded. The system is then completed at block 536.

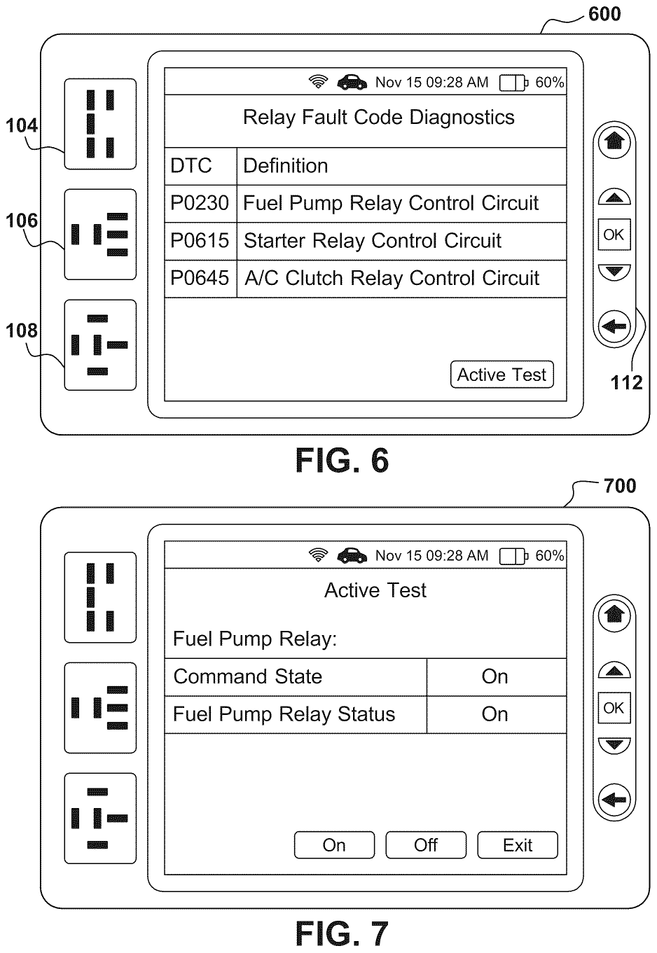

FIGS. 6 through 9 illustrate an example embodiment of a user interface sequence in conjunction with a relay testing operation using a tester such as scan tool 102 of FIG. 1. FIG. 6 illustrates a user interface view 600 wherein detected DTCs are displayed and defined for a user. Included are DTCs P0230 associated with a fuel pump relay control circuit, P0615 associated with a starter relay control circuit and P0645 associated with an air conditioner clutch relay control circuit. A test is selectable by navigation through the list via control buttons 114.

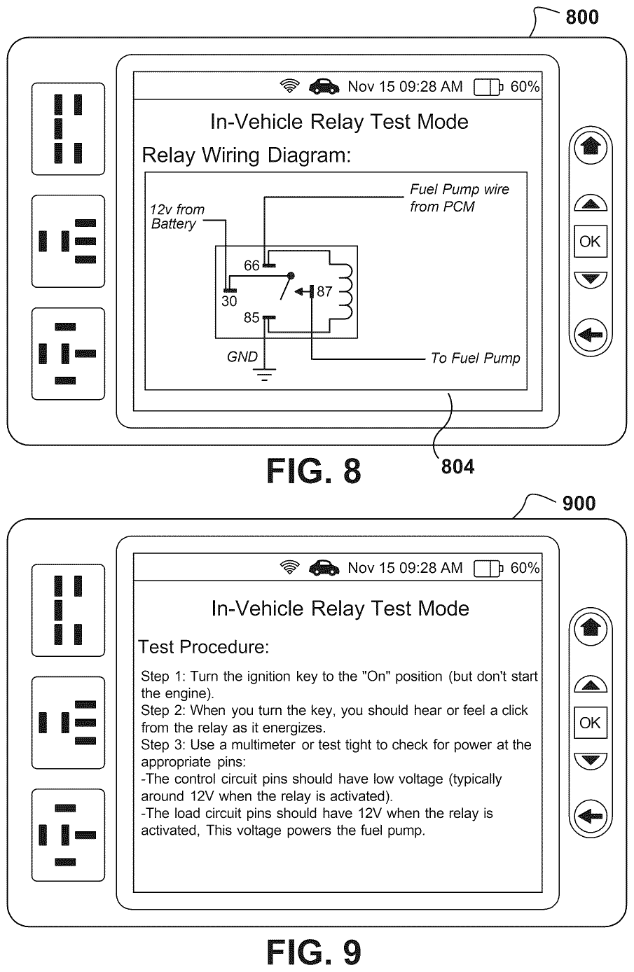

FIG. 7 illustrates a next user interface sequence 700 where a fuel pump relay associated with P0230 from FIG. 6 has been selected for testing. In the example, a fuel pump relay is available for in situ testing. FIG. 8 illustrates a next user interface sequence 800 wherein a display screen 804 depicts a relay diagram for the fuel pump relay is shown to assist a user in placement of test probes, such as probes for a multimeter, suitably configured for testing one or more of current, ac voltage, dc voltage or resistance. FIG. 9 illustrates a next user interface sequence 800 wherein in-situ relay testing instructions are shown, thus enabling in situ testing of the fuel pump relay.

The particulars shown herein are by way of example only for purposes of illustrative discussion, and are not presented in the cause of providing what is believed to be most useful and readily understood description of the principles and conceptual aspects of the various embodiments of the present disclosure. In this regard, no attempt is made to show any more detail than is necessary for a fundamental understanding of the different features of the various embodiments, the description taken with the drawings making apparent to those skilled in the art how these may be implemented in practice.

1. A system for identifying and testing vehicle electromechanical actuators comprising:
a processor and associated memory;
a network interface;
a user interface including a user input and a display;
an input configured to receive vehicle on-board diagnostic (OBD) information for an associated vehicle, the OBD information including vehicle diagnostic codes;
a test socket configured to receive an electromechanical actuator for testing;
the processor configured to:
identify a candidate electromechanical actuator in accordance with the received OBD information,
indicate the candidate electromechanical actuator on the display,
show OBD information associated with the candidate electromechanical actuator on the display,
show a location of the candidate electromechanical actuator on the display,
determine whether the candidate electromechanical actuator identified in accordance with the received OBD information is available for in situ vehicle testing,
when the candidate electromechanical actuator is determined to be available for in situ testing, show instructions for in situ testing of the candidate electromechanical actuator on the display,
when the candidate electromechanical actuator is determined to be unavailable for in situ vehicle testing
show instructions on the display for locating and removing the candidate electromechanical actuator from the vehicle,
show instructions on the display for inserting the candidate electromechanical actuator into the test socket,
perform a test sequence on the seated candidate electromechanical actuator,
show a test result for the tested candidate electromechanical actuator on the display,
show instructions for re-seating the candidate electromechanical actuator into the vehicle on the display when the test result indicates a pass,
show instructions for replacing the candidate electromechanical actuator on the display when the test result indicates a fail.

2. The system for identifying and testing vehicle electromechanical actuators of claim 1 wherein the OBD information further includes vehicle identification information, and wherein the processor is further configured to identify properties of the candidate electromechanical actuator in accordance with the vehicle identification information.

3. The system for identifying and testing vehicle electromechanical actuators of claim 2 further comprising a plurality of electromechanical actuator sockets, wherein the processor is further configured to show instructions corresponding to identification of which actuator socket is designated as the test socket.

4. The system for identifying and testing vehicle electromechanical actuators of claim 3 wherein the displayed instructions include a wiring diagram of the candidate electromechanical actuator showing electrical contact points for testing of the candidate electromechanical actuator in situ.

5. The system for identifying and testing vehicle electromechanical actuators of claim 4 wherein the candidate electromechanical actuator is a relay or a solenoid.

6. The system for identifying and testing vehicle electromechanical actuators of claim 5 wherein the processor is further configured to:
determine one or more tests associated with the vehicle diagnostic codes; and
generate the test sequence in accordance with the one or more tests.

7. The system for identifying and testing vehicle electromechanical actuators of claim 6 wherein the processor is further configured to:
determine abnormal results;
modify the test sequence in accordance with determined abnormal results; and
perform the modified test sequence on the seated candidate electromechanical actuator.

8. The system for identifying and testing vehicle electromechanical actuators of claim 1 wherein the processor is further configured to autonomously facilitate sending an active test command in response to determining that the candidate electromechanical actuator is available for in situ vehicle testing.

9. The system for identifying and testing vehicle electromechanical actuators of claim 1 wherein the processor is further configured to autonomously monitor for a trend in the OBD information in response to receipt of the OBD information.

10. The system for identifying and testing vehicle electromechanical actuators of claim 1 wherein the processor is further configured to autonomously prioritize a diagnostic action in response to detection of a prescribed diagnostic factor.

11. The system for identifying and testing vehicle electromechanical actuators of claim 1 wherein the processor is further configured to autonomously implement testing protocols in response to detection of a prescribed environmental factor.

12. The system for identifying and testing vehicle electromechanical actuators of claim 1, wherein the processor is configured to implement remaining one or more steps of the test sequence in response to determining an issue with the candidate electromechanical actuator in accordance with received OBD information.

13. The system for identifying and testing vehicle electromechanical actuators of claim 1, wherein the processor is further configured to receive OBD information and implement remaining steps of the test sequence in response to receipt of the OBD information.

14. The system for identifying and testing vehicle electromechanical actuators of claim 1, wherein the processor is further configured to autonomously implement the steps of:
identifying the candidate electromechanical actuator on the display,
showing OBD information associated with the candidate electromechanical actuator on the display,
showing the location of the candidate electromechanical actuator on the display,
determining whether the candidate electromechanical actuator is available for in situ vehicle testing,
in response to determining the issue with the candidate electromechanical actuator in accordance with the received OBD information.

15. A method for identifying and testing vehicle electromechanical actuators, comprising:
receiving, by a processor, vehicle on-board diagnostic (OBD) information for an associated vehicle, the OBD information including vehicle diagnostic codes;
determining, by the processor, an issue with a candidate electromechanical actuator based on the received OBD information;
identifying, by the processor, the candidate electromechanical actuator on a display;
showing, by the processor, OBD information associated with the candidate electromechanical actuator on the display;
showing, by the processor, a location of the candidate electromechanical actuator on the display;
determining, by the processor, whether the candidate electromechanical actuator identified in accordance with the received OBD information is available for in situ vehicle testing;
when the candidate electromechanical actuator is determined to be available for in situ testing:
displaying instructions for in situ testing of the candidate electromechanical actuator on the display;
when the candidate electromechanical actuator is determined to be unavailable for in situ vehicle testing
displaying instructions on the display for locating and removing the candidate electromechanical actuator from the vehicle;
displaying instructions on the display for inserting the candidate electromechanical actuator into a test socket;
performing, by the processor, a test sequence on the seated candidate electromechanical actuator;
displaying a test result for the tested candidate electromechanical actuator on the display;
displaying instructions for re-seating the candidate electromechanical actuator into the vehicle on the display when the test result indicates a pass;
displaying instructions for replacing the candidate electromechanical actuator on the display when the test result indicates a fail.

16. The method of claim 15, further comprising:
receiving vehicle identification information as part of the OBD information; and
identifying properties of the candidate electromechanical actuator based on the vehicle identification information.

17. The method of claim 16, further comprising:
designating one of a plurality of electromechanical actuator sockets as a test socket; and
displaying instructions corresponding to the identification of the test socket.

18. The method of claim 17, further comprising displaying a wiring diagram of the candidate electromechanical actuator showing electrical contact points for in situ testing of the candidate electromechanical actuator.

19. The method of claim 18, wherein the candidate electromechanical actuator is a relay or a solenoid.

20. The method of claim 19, further comprising:
determining one or more tests associated with the vehicle diagnostic codes; and
generating the test sequence based on the one or more tests.

21. The method of claim 20, further comprising:
determining abnormal results based on the test sequence;
modifying the test sequence in accordance with the determined abnormal results; and
performing the modified test sequence on the seated candidate electromechanical actuator.

22. A non-transitory computer-readable medium storing instructions that, when executed by a processor, cause the processor to perform a method for identifying and testing vehicle electromechanical actuators, the method comprising:
receiving vehicle on-board diagnostic (OBD) information for an associated vehicle, the OBD information including vehicle diagnostic codes;
determining an issue with a candidate electromechanical actuator based on the received OBD information;
identifying the candidate electromechanical actuator on a display;
showing OBD information associated with the candidate electromechanical actuator on the display;
showing a location of the candidate electromechanical actuator on the display;
determining whether the candidate electromechanical actuator identified by the received OBD information is available for in situ vehicle testing;
displaying instructions for in situ testing of the candidate electromechanical actuator on the display when the candidate electromechanical actuator is determined to be available for in situ testing;
displaying instructions on the display for locating and removing the candidate electromechanical actuator from the vehicle when the candidate electromechanical actuator is determined to be unavailable for in situ vehicle testing:
displaying instructions on the display for inserting the candidate electromechanical actuator into a test socket,
performing a test sequence on the seated candidate electromechanical actuator,
displaying a test result for the tested candidate electromechanical actuator on the display,
displaying instructions for re-seating the candidate electromechanical actuator into the vehicle on the display when the test result indicates a pass,
displaying instructions for replacing the candidate electromechanical actuator on the display when the test result indicates a fail.

23. The non-transitory computer-readable medium of claim 22, wherein the OBD information further includes vehicle identification information, and wherein the instructions further cause the processor to identify properties of the candidate electromechanical actuator based on the vehicle identification information.

24. The non-transitory computer-readable medium of claim 23, wherein the instructions further cause the processor to designate one of a plurality of electromechanical actuator sockets as a test socket and to display instructions corresponding to the identification of the test socket.

25. The non-transitory computer-readable medium of claim 24, wherein the instructions further cause the processor to display a wiring diagram of the candidate electromechanical actuator showing electrical contact points for in situ testing of the candidate electromechanical actuator.

26. The non-transitory computer-readable medium of claim 25, wherein the candidate electromechanical actuator is a relay or a solenoid.

27. The non-transitory computer-readable medium of claim 26, wherein the instructions further cause the processor to:
determine one or more tests associated with the vehicle diagnostic codes;
generate the test sequence based on the one or more tests;
determine abnormal results based on the test sequence;
modify the test sequence in accordance with determined abnormal results; and
perform the modified test sequence on the seated candidate electromechanical actuator.

28. A system for identifying and testing vehicle electromechanical actuators comprising:
a processor and associated memory;
a network interface;
and
an input configured to receive vehicle diagnostic information for an associated vehicle, the vehicle diagnostic information comprising vehicle identification data identifying the vehicle;
the processor configured to:
identify a suspect electromechanical actuator in accordance with the received vehicle diagnostic information,
determine whether the suspect electromechanical actuator identified in accordance with the received vehicle diagnostic information is available for in situ vehicle testing,
when the suspect electromechanical actuator is determined to be available for in situ testing, communicate an indicator to an associated user device for in situ testing of the suspect electromechanical actuator,
when the suspect electromechanical actuator is determined to be unavailable for in situ vehicle testing
communicate an indicator to the associated user device to
remove the suspect electromechanical actuator from the vehicle,
perform a test sequence on the suspect electromechanical actuator when the suspect electromechanical actuator is seated in a socket,
output a test result for a tested electromechanical actuator on the associated user device, place the tested electromechanical actuator back in the vehicle when the test result indicates a pass, and
replace the tested electromechanical actuator when the test result indicates a fail.

29. The system for identifying and testing vehicle electromechanical actuators of claim 28 wherein the vehicle identification data is comprised of the vehicles' vehicle identification number (VIN), and wherein the test sequence corresponds to the VIN.

30. A system for identifying and testing vehicle electromechanical actuators comprising:
a processor and associated memory, the memory storing vehicle identification data identifying an associated vehicle;
a data interface configured to receive diagnostic data retrieved from the vehicle;
a user interface including a user input interface and a user output interface;
one or more sockets configured to receive an electromechanical actuator;
a network interface configured to communicate the vehicle identification data and the vehicle diagnostic data to an associated cloud server;
the network interface further configured to receive test data from the cloud server responsive to the vehicle identification data and the vehicle diagnostic data, the test data identifying one or more suspect electromechanical actuators installed in the vehicle and a test process for testing the one or more suspect electromechanical actuators, wherein the test data includes data specifying whether each of the one or more electromagnetic actuators is available for in situ testing while installed in the vehicle;
the processor configured to communicate an indicator on the user output interface indicative of whether each of the one or more electromechanical actuators identified by the test data is available for in situ testing;
the processor further configured to generate an indicator on the user output interface directing a user to complete in situ testing of the one or more electromechanical actuators when available; and
the processor further configured to perform a test on the one or more electromechanical actuators while mounted in the one or more sockets when in situ testing is not available.
